(19) United States
(12) Patent Application Publication
(10) Pub. No.: US 2016/0149098 A1
(43) Pub. Date: May 26, 2016

(54) LIGHT EMITTING DIODE PACKAGE AND DISPLAY DEVICE HAVING THE SAME

(71) Applicant: Samsung Display Co., Ltd., Yongin-si (KR)

(72) Inventors: Hee-Kwang SONG, Suwon-si (KR); Jung Hyun KIM, Seoul (KR); Seokhyun NAM, Seoul (KR); Juyoung YOON, Seoul (KR)

(21) Appl. No.: 14/804,762

(22) Filed: Jul. 21, 2015

(30) Foreign Application Priority Data
Nov. 26, 2014 (KR) 10-2014-0166649

(51) Int. Cl. H01L 33/50; H01L 25/075; H01L 33/54; F21V 8/00; F21K 99/00

(52) U.S. Cl. CPC H01L 33/507; G02B 6/0026; G02B 6/0073; G02B 6/0068; F21K 9/54; H01L 33/54; H01L 25/0753; H01L 2933/0091

(57) ABSTRACT

A light emitting diode package includes a body portion including a planar portion and a sidewall portion bent upward from the planar portion to surround an edge of the planar portion, a first light emitting diode disposed on the planar portion and emitting a first light having a first color, and a second light emitting diode disposed on the planar portion to be spaced apart from the first light emitting diode by a predetermined distance and emitting a second light having a second color different from the first color.

### CLAIM OF PRIORITY

This U.S. non-provisional patent application claims the priority of and all the benefits accruing under 35 U.S.C. §119 of Korean Patent Application No. 10-2014-0166649, filed on Nov. 26, 2014 in the Korean Intellectual Property Office (KIPO), the contents of which are hereby incorporated by reference in its entirety.

### BACKGROUND OF THE INVENTION

1. Field of Disclosure

The present disclosure relates to a light emitting diode package and a display device having the same. More particularly, the present disclosure relates to a light emitting diode package capable of improving a chrominance and a display device having the light emitting diode package.

2. Description of the Related Art

A light emitting device, e.g., a light emitting diode, is a kind of semiconductor device that converts electrical energy to light and is spotlighted as a next-generation light source to replace a conventional fluorescent lamp and an incandescent lamp.

The light emitting diode has extremely low power consumption compared to the incandescent lamp that heats tungsten to generate the light or the fluorescent lamp generating the light using an ultraviolet ray that collides with fluorescent substance since the light emitting diode emits the light using the semiconductor device.

In addition, the light emitting diode generates the light using an electric potential gap of the semiconductor device, and thus the light emitting diode has advantages, such as a long life-span, a fast response speed time, an eco-friendly characteristic, etc., compared to a conventional light source.

Accordingly, researches have been carried out to replace the conventional light source with the light emitting diode, and the light emitting diode is widely applied to various fields, e.g., various lamps, a liquid crystal display device, an electric sign board, a street light, etc., as the light source.

### SUMMARY OF THE INVENTION

The present disclosure provides a light emitting diode package capable of providing a light having uniform color in accordance with a beam spread angle.

The present disclosure provides a display device having uniform color reproducibility over an entire surface of a display area thereof.

Embodiments of the inventive concept provide a light emitting diode package including a body portion including a planar portion and a sidewall portion bent upward from the planar portion to surround an edge of the planar portion, a first light emitting diode disposed on the planar portion and emitting a first light having a first color, and a second light emitting diode disposed on the planar portion to be spaced apart from the first light emitting diode by a predetermined distance and emitting a second light having a second color different from the first color. The distance is in a range equal to or greater than about 0.65 mm and equal to or smaller than about 0.85 mm.

The first light is mixed with the second light to generate a white color light.

The first color is a green color and the second color is a magenta color.

The light emitting diode package further includes a first sealing member spaced apart from the first light emitting diode to cover the second light emitting diode and converting a wavelength of the second light emitted from the second light emitting diode to generate a third light having a third color different from the first and second colors. The first light having the first color is mixed with the third light having the third color to generate the white color light.

The second color is a blue color and the first sealing member includes a red fluorescent substance.

The light emitting diode package further includes a second sealing member to protect the first and second light emitting diodes. The planar portion and the sidewall portion define a predetermined inner space and the second sealing member is filled in the inner space.

The second sealing member is a transparent resin.

The second sealing member includes metal oxide particles distributed in the transparent resin.

The metal oxide particles include silicon oxide or titanium oxide.

A distribution amount (content) of the metal oxide particles with respect to the transparent resin is in a range from about 7% to about 15%.

Embodiments of the inventive concept provide a display device including an accommodating unit including an inner space defined therein, a display panel accommodated in the inner space, and a light source accommodated in the inner space and generating a first light having a first color. The light source includes a circuit board and at least one light emitting diode package disposed on the circuit board, receiving an electrical signal from the circuit board, and generating the first light. The light emitting diode package includes a body portion, a first light emitting diode coupled to the body portion and emitting a second light having a second color different from the first color in response to the electrical signal, and a second light emitting diode spaced apart from the first light emitting diode by a predetermined distance, coupled to the body portion, and emitting a third light having a third color different from the first and second colors in response to the electrical signal. The second color is mixed with the third color to generate the first color, and the distance is in a range equal to or greater than about 0.65 mm and equal to or smaller than about 0.85 mm.

The first color is a white color, the second color is a green color, and a third color is a magenta color.

The light emitting diode package further includes a sealing member filled in the body portion to protect the first and second light emitting diodes. The sealing member includes a transparent resin portion filled in the body portion to cover the first and second light emitting diodes and at least one metal oxide particle distributed in the resin portion, and a content of the metal oxide particle is in a range from about 7% to about 15% with respect to the resin portion.

The metal oxide particle includes at least one of silicon oxide or titanium oxide.

The display device further includes a light guide member accommodated in the inner space and including a first surface facing the display panel, a second surface opposite to the first surface, and a plurality of connection surfaces connecting the first surface and the second surface. The light source is disposed to face at least one connection surface of the connection surfaces, and the light guide member receives the first light through the connection surface facing the light source and the first light exits through the first surface.

According to the above, the light emitting diode package includes the light emitting diodes spaced apart from each other by the distance and emitting the lights having different colors. The distance is in the range equal to or greater than about 0.65 mm and equal to or smaller than about 0.85 mm. The angular section of the light emitting diode package, in which the lights emitted from the light emitting diodes are overlapped, is maximized, and thus the chrominance caused by the beam spread angle is improved.

The light emitting diode package includes the sealing member including the metal oxide particles. Therefore, the lights emitted from the light emitting diodes are easily mixed with each other, and thus the uniformity of the light emitted from the light emitting diode package is improved.

The display device includes the light emitting diode package, so that the light having the uniform color and brightness is provided to the entire surface of the display area. Thus, the display device has improved color reproducibility over the entire surface of the display area.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings, in which like reference symbols indicate the same or similar components, wherein:

FIG. 1 is an exploded perspective view showing a display device according to an exemplary embodiment of the present disclosure;

FIG. 2A is a plan view showing a light emitting diode package according to an exemplary embodiment of the present disclosure;

FIG. 2B is a cross-sectional view taken along a line I-I′ shown in FIG. 2A;

FIG. 3 is a cross-sectional view showing a light emitting diode package according to an exemplary embodiment of the present disclosure;

FIG. 4 is a graph showing a chrominance of a light emitting diode package according to an exemplary embodiment of the present disclosure;

FIG. 5 is a cross-sectional view showing a light emitting diode package according to an exemplary embodiment of the present disclosure; and

FIG. 6 is a graph showing a chrominance of a light emitting diode package according to an exemplary embodiment of the present disclosure.

### DETAILED DESCRIPTION OF THE INVENTION

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90° or at other orientations) and the spatially relative descriptors used herein interpreted accordingly.

The terminology used herein is for the purpose of describing particular embodiments only and is not intended to be limiting of the invention. As used herein, the singular forms, “a”, “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present invention will be explained in detail with reference to the accompanying drawings.

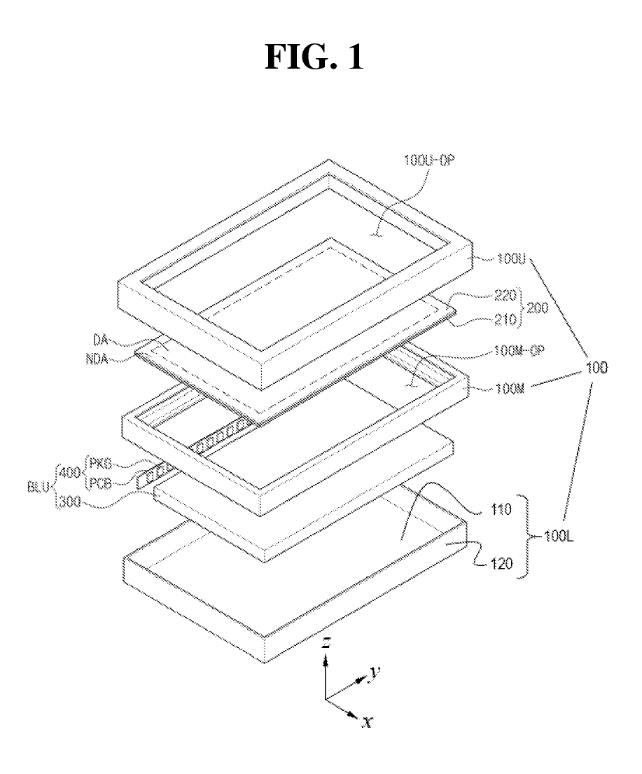

FIG. 1 is an exploded perspective view showing a display device according to an exemplary embodiment of the present disclosure.

Referring to FIG. 1, the display device includes accommodating members, a display panel 200, and a backlight unit BLU.

The accommodating members include an upper protective member 100U, a lower protective member 100L, and an intermediate protective member 100M. The upper and lower protective members 100U and 100L are coupled to each other to define an outer surface of the display device.

The upper protective member 100U is disposed above the display panel 200. The upper protective member 100U is provided with an opening portion 100U-OP formed therethrough to expose a display area DA of the display panel 200. The upper protective member 100U covers a non-display area NDA of the display panel 200. The non-display area NDA is disposed adjacent to the display area DA and an image is not displayed in the non-display area NDA.

The lower protective member 100L is disposed under the display panel 200. The lower protective member 100L includes a bottom portion 110 and a sidewall portion 120 bent upward from the bottom portion 110.

The bottom portion 110 has a substantially rectangular shape. The sidewall portion 120 is bent from four sides of the bottom portion 110 to define a predetermined inner space.

The backlight unit BLU is accommodated in the inner space. However, the shape of the bottom portion 110 should not be limited to the rectangular shape as long as the backlight unit BLU and the display panel 200 are accommodated in the inner space.

The intermediate protective member 100M is disposed between the upper protective member 100U and the lower protective member 100L. The intermediate protective member 100M is provided with a predetermined opening portion 100M-OP formed therethrough.

The intermediate protective member 100M has a substantially rectangular frame shape overlapped with the non-display area NDA of the display panel 200. The intermediate protective member 100M is disposed under the display panel 200 to support the display panel 200. The intermediate protective member 100M may be omitted.

The display panel 200 receives the light from the backlight unit BLU to generate the image. The display panel 200 is a transmissive or transflective display panel. For instance, the display panel 200 may be, but not limited to, a liquid crystal display panel or an electrophoretic display panel. In the present exemplary embodiment, the liquid crystal display panel including a first substrate 210 and a second substrate 220 will be described as the display panel 200.

The second substrate 220 is disposed on the first substrate 210. Although not shown in figures, each of the first and second substrates 210 and 220 includes a conductive layer (not shown) and an insulating layer (not shown) to insulate the conductive layer from others.

A liquid crystal layer (not shown) is disposed between the first and second substrates 210 and 220. The liquid crystal layer includes liquid crystal molecules aligned in accordance with an electric potential difference between the first and second substrates 210 and 220. The display panel 200 controls an amount of the light passing through the liquid crystal molecules to display a desired image.

The backlight unit BLU includes a light guide member 300 and a light source 400. The light guide member 300 receives the light from the light source 400. The light guide member 300 guides the light from the light source 400 to the display panel 200.

The light guide member 300 includes an upper surface facing the display panel 200, a lower surface facing the lower protective member 100L, and a plurality of connection surfaces connecting the upper and lower surfaces. The light guide member 300 receives the light through at least one of the connection surfaces and guides the light to the display panel 200 through the upper surface.

The light source 400 is disposed on at least one of the connection surfaces. The light source 400 includes a circuit board PCB and at least one light emitting diode package PKG mounted on the circuit board PCB. Although not shown in figures, metal lines are disposed on the circuit board PCB.

The light emitting diode package PKG is provided in a plural number and the light emitting diode packages PKG are arranged in a line shape along the connection surface. The light emitting diode package PKG is electrically connected to the circuit board PCB through the metal lines. The light emitting diode package PKG receives an electrical signal from the circuit board PCB to generate the light.

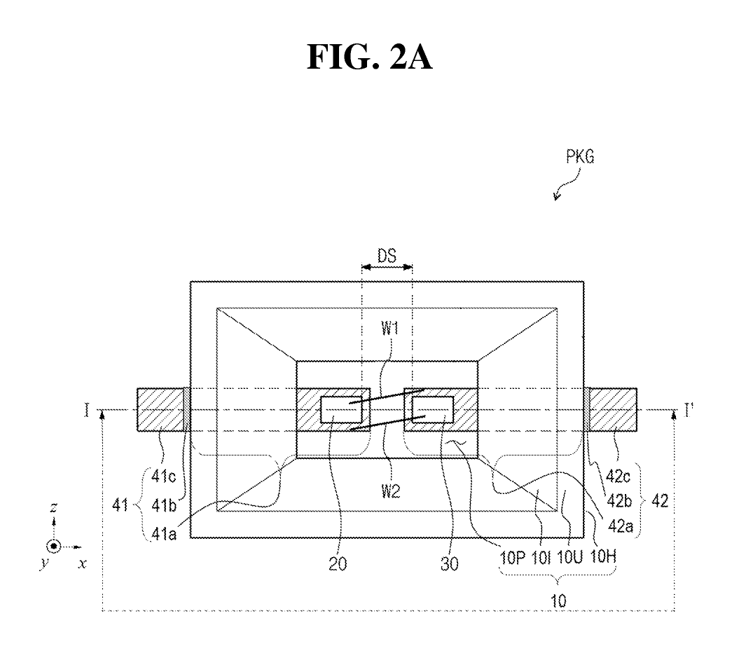

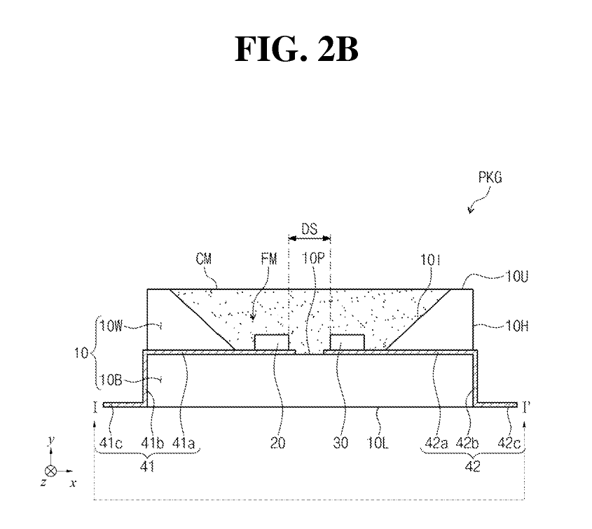

FIG. 2A is a plan view showing the light emitting diode package PKG according to an exemplary embodiment of the present disclosure and FIG. 2B is a cross-sectional view taken along a line I-I′ shown in FIG. 2A. Hereinafter, the light emitting diode package PKG will be described in detail with reference to FIGS. 2A and 2B. Each of the light emitting diode packages PKG shown in FIG. 1 may have the same structure and function as those of the light emitting diode package PKG shown in FIG. 1.

The light emitting diode package PKG includes a body portion 10, a first light emitting diode 20, a second light emitting diode 30, a first lead 41, and a second lead 42.

The body portion 10 defines an outer shape of the light emitting diode package PKG. The body portion 10 holds the first light emitting diode 20, the second light emitting diode 30, the first lead 41, and the second lead 42.

The body portion 10 includes an insulating material or a conductive material. For instance, the body portion 10 includes at least one of polyphthalamide (PPA), a resin material, such as epoxy, silicon carbide, silicon, aluminum nitride, metal, photosensitive glass (PSG), and sapphire (Al₂O₃).

The body portion 10 may have various shapes, e.g., a polygonal shape, a circular shape, an oval shape, etc., when viewed in a plan view. In the present exemplary embodiment, the body portion 10 has a substantially quadrangular shape when viewed in a plan view.

The body portion 10 includes a planar portion 10B and a sidewall portion low connected to the planar portion 10B. The planar portion 10B includes a bottom surface 10L, a mounting surface 10P facing the bottom surface 10L, and a side surface (not shown) connecting the planar portion 10B and the bottom surface 10L. The light emitting diodes 20 and 30 are mounted on the mounting surface 10P.

The sidewall portion 10W is disposed along an outer portion of the planar portion 10B and bent upward from the planar portion 10B. The sidewall portion 10W allows the light emitted from the light emitting diodes 20 and 30 to exit through an upper portion of the light emitting diode package PKG. The sidewall portion 10W prevents a light leakage phenomenon from occurring in the light emitting diode package PKG.

The sidewall portion 10W includes an upper surface 10U, an outer surface 10H, and an inner side surface 10I. The upper surface 10U is protruded upward from the mounting surface 10P. The outer surface 10H is connected to the side surface of the planar portion 10B to define an outer surface of the light emitting diode package PKG.

The inner side surface 10I is disposed along an edge of the mounting surface 10P. The inner side surface 10I may be inclined from the mounting surface 10P.

The inner side surface 10I connects the mounting surface 10P and the upper surface 10U. The mounting surface 10P and the inner side surface 10I define a predetermined cavity in the body portion 10.

The cavity has a shape in which an upper portion thereof is opened. The cavity has a recess shape, a cup shape, or a tube shape having a predetermined curvature, but it should not be limited thereto or thereby.

Although not shown in figures, a reflective coating layer may be disposed on the mounting surface 10P and the inner side surface 10I. For instance, the coating layer includes a reflective metal, e.g., aluminum, gold, silver, copper, etc., or a white photo solder resist (PSR) ink. The coating layer reflects the light emitted from the first and second light emitting diodes 20 and 30 to improve a light collectivity and a light-emitting efficiency of the light emitting diode package PKG.

The light emitting diode package PKG may further include a sealing member FM filled in the cavity. The sealing member FM covers the first and second light emitting diodes 20 and 30 to protect the first and second light emitting diodes 20 and 30.

The sealing member FM includes a transparent insulating material. For instance, the sealing member FM includes a resin-based material such as epoxy or silicon.

In this case, the light emitting diode package PKG may further include a cover member CM that coupled to the upper surface 10U. The cover member CM covers the cavity and seals the sealing member FM. The cover member CM includes an insulating material having high transmittance to reduce a loss of the light emitted from the first and second light emitting diodes 20 and 30.

The first and second light emitting diodes 20 and 30 are disposed on the mounting surface 10P. The first light emitting diode 20 emits the light having a first color (hereinafter, referred to as a first color light) and the second light emitting diode 30 emits the light having a second color (hereinafter, referred to as a second color light).

The first color is different from the second color. The first and second light emitting diodes 20 and 30 emit the first and second color lights to the cavity.

The first and second color lights respectively emitted from the first and second light emitting diodes 20 and 30 are mixed with each other in the cavity. The light emitting diode package PKG generates a third color light obtained by mixing the first color light with the second color light.

The third color light may be, but not limited to, a white color light.

Meanwhile, the first and second color lights respectively emitted from the first and second light emitting diodes 20 and 30 are diffused by the sealing member FM such that the first and second color lights are uniformly mixed with each other. Since the light emitting diode package PKG includes the sealing member FM, the light emitting diode package PKG emits the light with uniform brightness, and thus a color purity of the light is improved.

The first light emitting diode 20 generates the light in response to a driving voltage applied thereto through first and second electrodes. The first light emitting diode 20 has a structure in which an n-type semiconductor layer, an active layer, and a p-type semiconductor layer are sequentially stacked one on another.

The first light emitting diode 20 includes a chemical compound semiconductor including a group III element and a group V element. The chemical compound semiconductor including the group III element forms the p-type semiconductor layer and the chemical compound semiconductor including the group V element forms the n-type semiconductor layer. For instance, the first light emitting diode 20 includes at least one chemical compound semiconductor of AlInGaN, InGaN, GaN, GaAs, InGaP, AlInGaP, InP, and InGaAs.

When the driving voltage is applied to the first light emitting diode 20, electrons are recombined with holes in the first light emitting diode 20 and the first color light is generated. In the present exemplary embodiment, the second light emitting diode 30 has the same structure as that of the first light emitting diode 20.

The first and second light emitting diodes 20 and 30 are disposed on the same plane surface and spaced apart from each other by a predetermined distance DS. The distance DS corresponds to a straight distance between a position of the side surface of the first light emitting diode 20, which is nearest to the second light emitting diode 30, and a position of the side surface of the second light emitting diode 30, which is nearest to the first light emitting diode 20.

In the present exemplary embodiment, the distance DS is determined in consideration of a beam spread angle of the first light emitting diode 20 and a beam spread angle of the second light emitting diode 30. As an example, the distance DS is in a range from about 0.65 mm to about 0.85 mm.

The first and second leads 41 and 42 are disposed to be spaced apart from each other. The first and second leads 41 and 42 are electrically separated from each other.

The first and second leads 41 and 42 are respectively and electrically connected to the first and second light emitting diodes 20 and 30. In the present exemplary embodiment, the first and second light emitting diodes 20 and 30 are respectively connected to the first and second leads 41 and 42 through wires W1 and W2. The first and second leads 41 and 42 apply a source voltage to the first and second light emitting diodes 20 and 30, respectively.

The first lead 41 includes a first portion 41a inserted into the body portion 10 and second and third portions 41b and 41c exposed from the body portion 10.

The first portion 41a is disposed on the planar portion 10B and a portion of the first portion 41a is exposed to the cavity. The first portion 41a is electrically connected to the first light emitting diode 20.

The first light emitting diode 20 may be mounted on the first portion 41a. A conductive adhesive layer (not shown) may be further disposed between the first portion 41a and the first light emitting diode 20. Meanwhile, the first light emitting diode 20 may be disposed to be spaced apart from the first portion 41a and electrically connected to the first portion 41a through a separate wire.

The second portion 41b is connected to the first portion 41a and bent from a lower portion of the first portion 41a. The second portion 41b extends along the side surface of the planar portion 10B.

The third portion 41c is connected to the second portion 41b and extends after being bent from the second portion 41b. The third portion 41c is protruded outward from the body portion 10 when viewed in a plan view and electrically connected to the circuit board PCB (refer to FIG. 1).

The second lead 42 includes a first portion 42a, a second portion 42b, and a third portion 42c, which are sequentially connected to each other. In the present exemplary embodiment, the second lead 42 has the same shape as that of the first lead 41. Accordingly, detailed descriptions of the second lead 42 will be omitted.

Each of the first and second leads 41 and 42 includes a metal material. For instance, each of the first and second leads 41 and 42 includes at least one of titanium (Ti), copper (Cu), nickel (Ni), gold (Au), chromium (Cr), tantalum (Ta), platinum (Pt), tin (Sn), silver (Ag), and phosphorus (P). In addition, each of the first and second leads 41 and 42 has a structure of a single layer of metal or a structure having multiple metal layers.

FIGS. 2A and 2B show the light emitting diode package PKG including the first and second leads 41 and 42, but the number of the leads included in the light emitting diode package PKG should not be limited to two. That is, the light emitting diode package PKG may include three or more leads.

In addition, each of the first and second leads 41 and 42 may have various shapes. For instance, each of the first and second leads 41 and 42 may have a bar shape, a curved line shape surrounding the body portion 10, a plurality of island shapes connected to each other, or a branch shape in which the first and second leads 41 and 42 are divided into several parts.

Although not shown in figures, the light emitting diode package PKG may further include a protective device. The protective device is disposed on portions of the first and second leads 41 and 42. The protective device may be a thyristor, a zener diode, or a transient voltage suppression (TVS) diode. The protective device protects the first and second light emitting diodes 20 and 30 from an electro-static discharge (ESD).

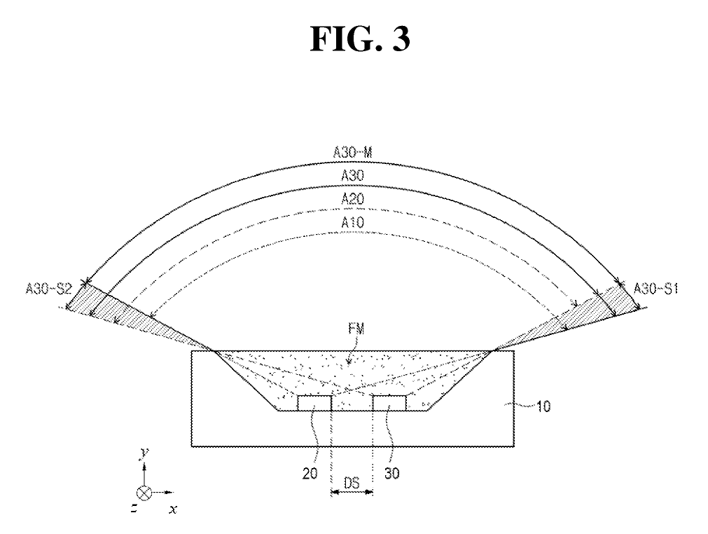

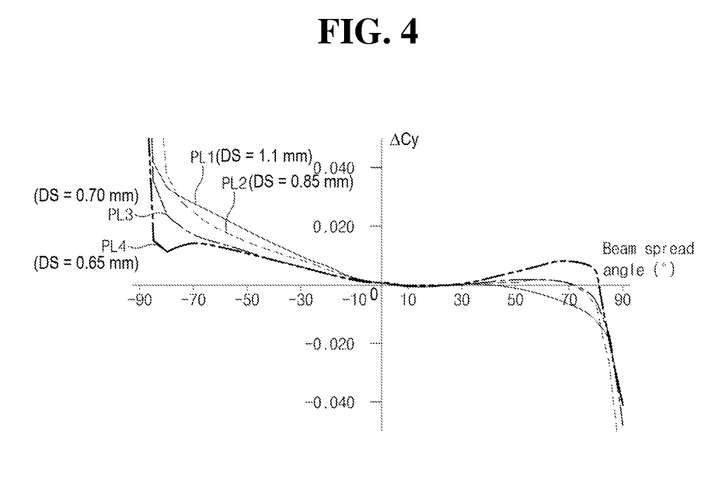

FIG. 3 is a cross-sectional view showing a light emitting diode package PKG according to an exemplary embodiment of the present disclosure and FIG. 4 is a graph showing a chrominance of a light emitting diode package PKG according to an exemplary embodiment of the present disclosure. Hereinafter, a light-emitting characteristic of the light emitting diode package PKG will be described with reference to FIGS. 3 and 4.

FIG. 3 shows light emission angular ranges of lights different from each other, i.e., a beam spread angle of the light emitting diode package PKG and elements in the light emitting diode package PKG.

The beam spread angle of the first light emitting diode 20 is represented by a first angular range A10 and the beam spread angle of the second light emitting diode 30 is represented by a second angular range A20. That is, the first angular range A10 represents the light emission angular range of the first color light and the second angular range A20 represents the light emission angular range of the second color light.

As shown in FIG. 3, the first and second angular ranges A10 and A20 are represented as a radial shape in which a cross section is a fan shape with respect to a corresponding element. Since the first and second light emitting diodes 20 and 30 are disposed to be spaced apart from each other when viewed in a plan view, the first and second angular ranges A10 and A20 include an overlapped angular sections and a non-overlapped angular sections.

The beam spread angle of the light emitting diode package PKG is represented by a third angular range A30. The third angular range A30 is divided into plural angular sections in accordance with the overlap between the first and second angular ranges A10 and A20.

The angular sections include a first angular section A30-M, a second angular section A30-S1, and a third angular section A30-S2 spaced apart from the second angular section A30-S1 such that the first angular section A30-M is disposed between the first and second angular sections A30-S1 and A30-S2. Different lights appear according to the angular sections.

The light having a mixed color appears in the first angular section A30-M. In detail, the third color light appears in the first angular section A30-M.

The first and second angular ranges A10 and A20 are overlapped with each other in the first angular section A30-M. Accordingly, the light emitted from the first light emitting diode 20 is mixed with the light emitted from the second light emitting diode 30 in the first angular section A30-M. Substantially, the first angular section A30-M corresponds to the beam spread angle of the third color light.

The light having one color appears in the second angular section A30-S1 and the third angular section A30-S2. In detail, the first color light appears in the second angular section A30-S1 and the second color light appears in the third angular section A30-S2.

The first and second angular ranges A10 and A20 are not overlapped with each other in the second and third angular section A30-S1 and A30-S2. Therefore, the light emitted from the first light emitting diode 20 appears in the second angular section A30-S1 and the light emitted from the second light emitting diode 30 appears in the third angular section A30-S2.

A rate of the second and third angular section A30-S1 and A30-S2 to the third angular range A30 is varied depending on the distance DS. In general, as the distance DS becomes smaller, the rate of the second and third angular sections A30-S1 and A30-S2 in the third angular range A30 becomes smaller.

The light emitting diode package PKG according to the present exemplary embodiment may reduce the rate of the second and third angular sections A30-S1 and A30-S2 by controlling the distance DS. Hereinafter, a variation in the light-emitting characteristic of the light emitting diode package PKG according to the distance DS will be described in detail with reference to FIG. 4.

FIG. 4 shows a color uniformity of each of various light emitting diode packages PKG according to the beam spread angle. Each light emitting diode package PKG includes light emitting diodes spaced apart from each other by different distances. The color uniformity is represented by a chrominance at each measuring position with respect to a position at which the beam spread angle is about zero. The chrominance is represented as viewed relative to a variation amount (ΔCy) of a Cy value of a color coordinate (CIE 1941).

In the present exemplary embodiment, the beam spread angle indicates the beam spread angle of the light emitted from the light emitting diode package PKG, i.e., the third angular range A30. The position, at which the beam spread angle is about zero, corresponds to a center position of the distance DS, and the measuring positions are arranged along the beam spread angle.

As shown in FIG. 4, the chrominance is measured in a angular range from about −90° to about 90° with respect to the center position of the light emitting diode package PKG when the light emitting diode package PKG is turned on. The positive angular range corresponds to a right angular sections of the center position of the light emitting diode package PKG and the negative angular range corresponds to a left angular sections of the center position of the light emitting diode package PKG.

A first graph PL1 shows the chrominance distribution according to the beam spread angle in a case that the distance DS is about 1.1 mm, a second graph PL2 shows the chrominance distribution according to the beam spread angle in a case that the distance DS is about 0.85 mm, a third graph PL3 shows the chrominance distribution according to the beam spread angle in a case that the distance DS is about 0.70 mm, and a fourth graph PL4 shows the chrominance distribution according to the beam spread angle in a case that the distance DS is about 0.65 mm.

As represented by the first to fourth graphs PL1 to PL4, the chrominance tends to increase as a distance from the center position of the light emitting diode package PKG increases. In particular, a slope of the first to fourth graphs PL1 to PL4 rapidly increases in the angular range from about −90° to about −70° or in the angular range from about 70° to about 90° compared to the angular range from about −70° to about 70°.

The angular range from about −70° to about 70° corresponds to the first angular section A30-M, the angular range from about −90° to about −70° corresponds to the second angular section A30-S1, and the angular range from about 70° to about 80° corresponds to the third angular section A30-S2.

The slopes of the first to fourth graphs PL1 to PL4 are sequentially reduced in the angular range in which the beam spread angle is negative. In detail, the slope of the first graph PL1 is the largest when the beam spread angle is in the angular range from about −70° to about 0°, and the slope of the fourth graph PL4 is the smoothest. Thus, as the distance DS becomes smaller in the angular range in which the beam spread angle is negative, the chrominance becomes smaller.

The slopes of the first to fourth graphs PL1 to PL4 are smooth in the angular range in which the beam spread angle is positive when compared to that in angular range in which the beam spread angle is negative. In addition, the slopes of the first to fourth graphs PL1 to PL4 are substantially similar to each other.

However, a difference between the slopes of the first to fourth graphs PL1 to PL4 occurs at a position at which the beam spread angle is about 70°. According to the first graph PL1 that shows the chrominance distribution in the case that the distance DS is largest, the chrominance increases while the beam spread angle increases.

The second and third graphs PL2 and PL3 have the slope that is smoother than that of the first graph PL1. The second and third graphs PL2 and PL3 have the slope closer to about zero when the beam spread angle is in the angular range from about 0° to about 70°. That is, when the distance DS is equal to or smaller than about 1.1 mm, the chrominance of the light emitted from the light emitting diode package PKG is reduced.

Meanwhile, the fourth graph PL4 has the negative slope at the position at which the beam spread angle is about 70°. An absolute value of the slope of the fourth graph PL4 is greater than an absolute value of the slope of the second graph PL2 or an absolute value of the slope of the third graph PL3. That is, the chrominance of the light emitted from the light emitting diode package PKG increases again when the distance DS is equal to or smaller than about 0.65 mm.

In general, as the light emitted from the light emitting diode package PKG has uniform brightness in the positive and negative angular ranges of the beam spread angle and the chrominance of the light is small, the light-emitting characteristic of the light emitting diode package PKG is improved.

The chrominance of the light emitted from the light emitting diode package PKG is improved as the distance DS is reduced. However, the chrominance of the light emitted from the light emitting diode package PKG is increased again when the distance DS becomes smaller than the predetermined distance. That is, the light emitting diode package PKG has the improved light-emitting characteristic when the distance DS is equal to or greater than about 0.65 mm and equal to or smaller than about 0.80 mm.

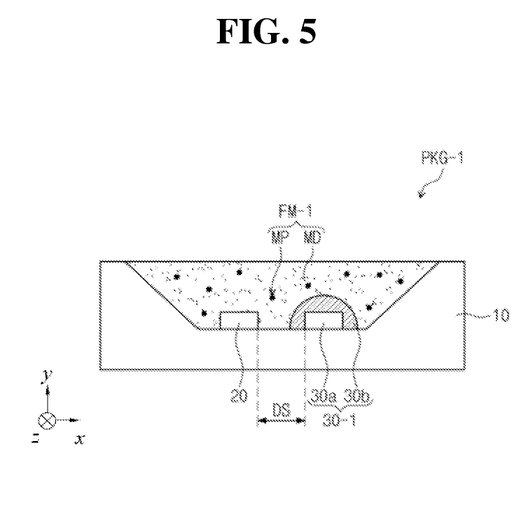

FIG. 5 is a cross-sectional view showing a light emitting diode package PKG-1 according to an exemplary embodiment of the present disclosure. Hereinafter, the light emitting diode package PKG-1 will be described in detail with reference to FIG. 5.

The light emitting diode package PKG-1 has the same structure and function as those of the light emitting diode package PKG shown in FIG. 3 except for a second light emitting diode 30-1 and a sealing member FM-1. In FIG. 5, the same reference numerals denote the same elements in FIG. 3, and thus detailed descriptions of the same elements will be omitted.

The light emitting diode package PKG-1 may further include the sealing member FM-1. The sealing member FM-1 includes a resin portion MD and at least one of scattering particles MP. In this embodiment, the sealing member FM-1 may comprises metal oxide particles MP.

The resin portion MD is filled in the cavity of the body portion 10 to cover the first and second light emitting diodes 20 and 30-1. The resin portion MD includes a transparent insulating material having high light transmittance. In the present exemplary embodiment, the resin portion MD corresponds to the sealing member FM shown in FIG. 3.

The metal oxide particles MP is disposed in the resin portion MD. The metal oxide particle MP is provides in a plural number and the metal oxide particles MP are distributed in the resin portion MD. The metal oxide particles MP include at least one of silicon oxide and titanium oxide.

The sealing member FM-1 includes the metal oxide particles MP, and thus the sealing member FM-1 improves a refractive index against the lights emitted from the first and second light emitting diodes 20 and 30-1. The light emitted from the first light emitting diode 20 and the light emitted from the second light emitting diode 30-1 are mixed with each other while being reflected or refracted by the metal oxide particles MP.

The second light emitting diode 30-1 emits the second color light. In the present exemplary embodiment, the second light emitting diode 30-1 includes a light emitting chip 30a and a sealing member 30b.

The light emitting chip 30a emits a fourth color light. The fourth color light has a color different from that of the first to third lights. In the present exemplary embodiment, the light emitting chip 30a may be, but not limited to, a light emitting diode.

The sealing member 30b covers the light emitting chip 30a. The sealing member 30b changes a wavelength of at least a portion of the fourth color light emitted from the light emitting chip 30a.

The sealing member 30b includes fluorescent substances. The fluorescent substances excite at least a portion of the fourth color light emitted from the light emitting chip 30a to convert the portion of the fourth color light to a light having a different wavelength.

The fluorescent substances include at least one of yittrium aluminum oxide garnet (YAG), terbium aluminum garnet (TAG), silicate, a nitride-base material, and an oxynitride-based material. The fluorescent substances include at least one of a red fluorescent substance, a green fluorescent substance, and a yellow fluorescent substance.

The fourth color light is converted to the second color light by the sealing member 30b. For instance, when the light emitting chip 30a emits a blue light and the sealing member 30b includes the red fluorescent substance, the second light emitting diode 30-1 emits a light having a magenta color. A wavelength of the blue light is converted by the fluorescent substances, and thus the blue light is converted to the magenta light.

The sealing member 30b may be omitted from the light emitting diode package PKG according to the present exemplary embodiment. In this case, the light emitting diode package PKG-1 may include the second light emitting diode 30 shown in FIG. 3.

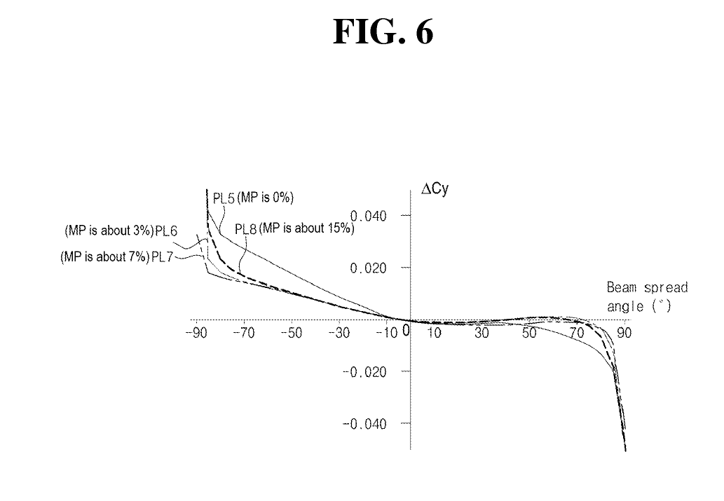

FIG. 6 is a graph showing a chrominance of a light emitting diode package PKG according to an exemplary embodiment of the present disclosure. Hereinafter, the optical characteristic of the light emitting diode package PKG according to the metal oxide particles MP will be described in detail with reference to FIG. 6.

FIG. 6 shows the chrominance distribution according to the beam spread angle in various embodiments in which a distribution amount of the metal oxide particles MP is changed. The distribution amount of the metal oxide particles MP is represented by a percentage of the content of the amount of the metal oxide particles MP included in the sealing member FM-1.

In the present exemplary embodiment, the metal oxide particles MP include silicon oxide (SiO2). Meanwhile, the method of measuring the chrominance distribution is substantially the same as that described with reference to FIG. 4.

A fifth graph PL5 shows the embodiment in which the sealing member FM-1 does not include the metal oxide particles MP, a sixth graph PL6 shows the embodiment in which the distribution amount of the metal oxide particles MP is about 3%, a seventh graph PL7 shows the embodiment in which the distribution amount of the metal oxide particles MP is about 7%, and an eighth graph PL8 shows the embodiment in which the distribution amount of the metal oxide particles MP is about 15%,

The distance DS is about 1.1 mm in the embodiment related to the fifth graph PL5 and the distance DS is about 0.7 mm in the embodiments related to the sixth, seventh, and eighth graphs PL6, PL7, and PL8. Accordingly, the fifth graph PL5 corresponds to the first graph PL1 (refer to FIG. 4).

As shown in FIG. 6, different from the first graph PL1, the slopes of the sixth, seventh, and eighth graphs PL6, PL7, and PL8 are smoothly represented due to the beam spread angle. This means that the optical characteristic of the light emitting diode package PKG-1 is improved as the amount of the metal oxide particles MP in the sealing member FM-1 increases.

Referring to the sixth, seventh, and eighth graphs PL6, PL7, and PL8, the slope of the seventh graph PL7 is smoothly represented in the positive and negative angular ranges of the beam spread angle. That is, when the distance DS is about 0.7 mm and the distribution amount of the metal oxide particles MP is about 7%, the chrominance of the light emitting diode package PKG-1 is effectively improved.

Although the exemplary embodiments of the present invention have been described, it is understood that the present invention should not be limited to these exemplary embodiments but various changes and modifications can be made by one ordinary skilled in the art within the spirit and scope of the present invention as hereinafter claimed.

What is claimed is:

1. A light emitting diode package comprising:
a body portion comprising a planar portion and a sidewall portion bent upward from the planar portion to surround an edge of the planar portion;
a first light emitting diode disposed on the planar portion and emitting a first light having a first color; and
a second light emitting diode disposed on the planar portion and emitting a second light having a second color different from the first color,
wherein the second light emitting diode is spaced apart from the first light emitting diode by a predetermined distance in a range equal to or greater than about 0.65 mm and equal to or smaller than about 0.85 mm.

2. The light emitting diode package of claim 1, wherein the first light is mixed with the second light to generate a white color light.

3. The light emitting diode package of claim 2, wherein the first color is a green color and the second color is a magenta color.

4. The light emitting diode package of claim 1, further comprising a first sealing member covering the second light emitting diode and converting a wavelength of the second light emitted from the second light emitting diode to generate a third light having a third color different from the first and second colors,
wherein the first sealing member is spaced apart from the first light emitting diode and the first light is mixed with the third light to generate the white color light.

5. The light emitting diode package of claim 4, wherein the second color is a blue color and the first sealing member having a red phosphor.

6. The light emitting diode package of claim 1, further comprising a second sealing member to protect the first and second light emitting diodes, wherein the planar portion and the sidewall portion define a predetermined inner space and the second sealing member is filled in the inner space.

7. The light emitting diode package of claim 6, wherein the second sealing member is a transparent resin.

8. The light emitting diode package of claim 7, wherein the second sealing member further comprises metal oxide particles distributed in the transparent resin.

9. The light emitting diode package of claim 8, wherein the metal oxide particles comprise at least one of silicon oxide and titanium oxide.

10. The light emitting diode package of claim 9, wherein a distribution amount (content) of the metal oxide particles with respect to the transparent resin is in a range from about 7% to about 15%.

11. A display device comprising:
an accommodating unit comprising an inner space defined in the accommodating unit;
a display panel accommodated in the inner space; and
a light source accommodated in the inner space and generating a first light having a first color, wherein the light source comprises a circuit board and at least one light emitting diode package disposed on the circuit board, receiving an electrical signal from the circuit board, and generating the first light, the light emitting diode package comprises a body portion;
a first light emitting diode coupled to the body portion and emitting a second light having a second color different from the first color in response to the electrical signal; and
a second light emitting diode spaced apart from the first light emitting diode by a predetermined distance, coupled to the body portion, and the second light emitting diode emitting a third light in response to the electrical signal, wherein the third light has a third color different from the first and second colors, and
wherein the second color is mixed with the third color to generate the first color, and
the distance is in a range equal to or greater than about 0.65 mm and equal to or smaller than about 0.85 mm.

12. The display device of claim 11, wherein the first color is a white color, the second color is a green color, and a third color is a magenta color.

13. The display device of claim 12, wherein the light emitting diode package further comprises a sealing member filled in the body portion to protect the first and second light emitting diodes, the sealing member comprises
a transparent resin portion filled in the body portion to cover the first and second light emitting diodes; and
at least one metal oxide particle distributed in the resin portion, and wherein the metal oxide particle has a content which is in a range from about 7% to about 15% with respect to the resin portion.

14. The display device of claim 13, wherein the metal oxide particle comprises at least one of silicon oxide or titanium oxide.

15. The display device of claim 14, further comprising a light guide member accommodated in the inner space and comprising a first surface facing the display panel,
a second surface opposite to the first surface, and
a plurality of connection surfaces connecting the first surface and the second surface,
wherein the light source is disposed to face at least one of the connection surfaces, and the light guide member receives the first light through the connection surface facing the light source and the first light exits through the first surface.
